(19) United States
(12) Patent Application Publication
(10) Pub. No.: US 2012/0048724 A1
(43) Pub. Date: Mar. 1, 2012

(54) Cylindrical Magnetron Sputter Source Utilizing Halbach Magnet Array

(76) Inventor: Paul S. McLeod, Berkeley, CA (US)

(21) Appl. No.: 12/873,259

(22) Filed: Aug. 31, 2010

(51) Int. Cl. C23C 14/35

(52) U.S. Cl. 204/192.12; 204/298.22

(57) ABSTRACT

A cylindrical magnetron sputtering cathode comprises a rotatable cylindrical sputtering target, a magnet assembly that includes a plurality of Halbach magnet arrays disposed within the rotatable cylindrical sputtering target and a magnetic magnet support and field shaper disposed within the sputtering target and to which the magnet assembly is attached.

### SUMMARY

Embodiments of the disclosure are generally directed to apparatuses and methods for depositing a thin film of a target material on a surface of a substrate held within the cathode sputter system. According to various embodiments, a cylindrical magnetron sputter source includes a rotatable cylindrical sputtering target and a stationary magnet assembly. The stationary magnet assembly includes a plurality of Halbach magnet arrays disposed within the cylindrical sputtering target. A magnetic magnet support and field plate is disposed within the cylindrical sputtering target, to which the magnet assembly is attached.

Each of the Halbach magnet arrays may comprise a centrally positioned unidirectional magnet with radially outwardly oriented polarity, a first laterally positioned unidirectional magnet with polarity oriented orthogonally downward with respect to the central magnetic, and a second laterally positioned unidirectional magnet with polarity oriented orthogonally upward with respect to the central magnet. The cylindrical magnetron sputter source may include a magnet assembly housing in which the magnet assembly is disposed. The magnet assembly housing is preferably hermetically attached to the magnetic magnet support and field plate.

According to various embodiments, a cylindrical magnetron sputter source includes a rotatable cylindrical sputtering target formed on a backing cylinder, and a magnet assembly that is disposed within the backing cylinder to be stationary relative to the rotatable cylindrical sputtering target. The magnet assembly includes a plurality of Halbach magnet arrays. A magnetic magnet support and field shaper is disposed within the backing cylinder. The magnet assembly may be disposed in a magnet assembly housing, which is preferably hermetically attached to the magnet support and field shaper. The magnet support and field shaper may include a plurality of bearings formed as a part thereof such that the bearings ride on an inside surface of the backing cylinder and prevent the magnet assembly housing from contacting the backing cylinder. Each of the Halbach magnet arrays may comprise a centrally positioned unidirectional magnet with radially outwardly oriented polarity, an upper laterally positioned unidirectional magnet with polarity oriented orthogonally downward with respect to the central magnet, and a lower laterally positioned unidirectional magnet with polarity oriented orthogonally upward with respect to the central magnet.

Various embodiments are directed to methods performed using a cathode sputter system. Methods are preferably performed in a cathode sputter system that uses a cylindrical magnetron sputter source electrically connected as a cathode electrode. The cylindrical magnetron sputter source preferably includes a rotatable cylindrical sputtering target, a stationary magnet assembly that includes a plurality of Halbach magnet arrays disposed within the cylindrical sputtering target, and a magnetic magnet support and field plate disposed within the cylindrical sputtering target and to which the magnet assembly is attached. Various methods involve evacuating the volume of the cathode sputter system in which a substrate is situated, introducing an inert gas into the evacuated volume, and applying a high voltage electric field between the cylindrical magnetron sputter source connected as a cathode electrode and an anode electrode within the cathode sputter system to generate a plasma within the evacuated volume. The cylindrical sputtering target is rotated while the plasma is present, and a thin film of the target material is deposited on the surface of the substrate held within the cathode sputter system.

The Halbach magnet arrays may each include a centrally positioned unidirectional magnet with radially outwardly oriented polarity, a first laterally positioned unidirectional magnet with polarity oriented orthogonally downward with respect to the central magnetic, and a second laterally positioned unidirectional magnet with polarity oriented orthogonally upward with respect to the central magnet.

According to various embodiments, methods are performed using a cathode sputter system which includes a cylindrical magnetron sputter source, electrically connected as a cathode electrode. The cylindrical magnetron sputter source preferably includes a rotatable cylindrical sputtering target formed on a backing cylinder and a magnet assembly that is disposed within the backing cylinder to be stationary relative to the rotatable cylindrical sputtering target. The magnet assembly preferably includes a plurality of Halbach magnet arrays, a magnetic magnet support and field shaper disposed within the backing cylinder, and a magnet assembly housing in which the magnet assembly is disposed. The magnet assembly housing is preferably hermetically attached to the magnet support and field shaper. The magnet support and field shaper preferably includes a plurality of bearings formed as a part thereof such that the bearings ride on an inside surface of the backing cylinder and prevent the magnet assembly housing from contacting the backing cylinder. Various methods performed using such a cathode sputter system involve evacuating the volume of the cathode sputter system in which a substrate is situated, introducing an inert gas into the evacuated volume, and applying a high voltage electric field between the cylindrical magnetron sputter source connected as a cathode electrode and an anode electrode within the cathode sputter system to generate a plasma within the evacuated volume. The method further involves rotating the cylindrical sputtering target while the plasma is present and depositing a thin film of the target material on the surface of the substrate held within the cathode sputter system.

These and other features and aspects which characterize various embodiments of the disclosure can be understood in view of the following detailed discussion and the accompanying drawings.

### BRIEF DESCRIPTION OF THE DRAWINGS

FIG. 1 is a cross section drawing illustrating an embodiment of a cylindrical magnetron sputter source utilizing a Halbach magnet array according to various embodiments; and

FIG. 2 is a cross section drawing illustrating magnetic flux lines of the cylindrical magnetron sputter source shown in FIG. 1.

### DETAILED DESCRIPTION

Sputter deposition apparatuses and processes according to various embodiments of the disclosure generally involve vaporizing a material to be deposited by ion bombardment of the surface of a target comprised of the material. The target forms part of a cathode assembly located within an evacuated chamber that contains an inert gas, such as for example, argon. A high voltage electric field is applied between the negatively charged cathode assembly and a positively charged anode electrode that is also located within the chamber. A plasma is thus formed within the chamber. The plasma comprises positively charged ions of the inert gas that are formed by collision of the atoms of the inert gas with electrons emanating from the cathode surface. The positively charged ions of the inert gas are attracted to the surface of the negatively charged cathode (i.e., the target), whereby particles of the target material are dislodged when the ions strike the target surface. The dislodged particles traverse the interior space of the chamber and deposit as a thin film on the surface(s) of at least one substrate that is positioned on a substrate support within the chamber.

Substantially increased deposition rates can be realized by utilizing a magnetic field in combination with the electric field in accordance with embodiments of the disclosure. In a magnetron sputtering process according to various embodiments, an arched magnetic field that is formed in a closed loop over the surface of the sputtering target is superimposed on the electric field. More specifically, a magnet assembly comprising a plurality of permanent magnets or electromagnets is provided behind the sputtering surface of the target such that magnetic flux lines from the magnet assembly extend from a first pole of the assembly through the target and emerge, extend and return through the target to a second pole of the magnet assembly, thereby forming a virtual “tunnel.”

When the magnet assembly forms this arched, closed-loop magnetic field or “racetrack,” electrons are advantageously trapped or confined in an annular region of the plasma adjacent the target surface. The trapped or confined electrons are swept about the closed loop racetrack under the combined influences of the electric and magnetic fields. As a consequence of the electron trapping and motion within the racetrack, the number of collisions between electrons and inert gas atoms to produce positively charged ions available for bombardment and, thus, for sputtering of the target surface, is greatly increased in the regions defined by the arched, closed-loop magnetic field.

According to various embodiments, a cylindrical magnetron sputter source comprises a rotatable cylindrical sputtering target, a stationary magnet assembly that includes a plurality of Halbach magnet arrays disposed within the cylindrical sputtering target, and a magnetic magnet support pole piece to which the magnet assembly is attached. Various embodiments described herein are based upon the recognition that certain unidirectionally polarized magnet arrays, known as “Halbach” arrays, are capable of providing magnetic fields that emerge from and re-enter sputtering targets to provide arched, closed loop magnetic field paths characteristic of typical magnetron magnet assemblies, without the loss of approximately one-half of the magnetic flux as occurs with such typical magnetron magnet assemblies.

As utilized herein, the term “Halbach magnet array” means an arrangement (e.g., an array) of permanent magnets that augments the magnetic field at one side, end or edge of the array while cancelling or reducing the magnetic field at the other side, end or edge of the array to substantially zero.

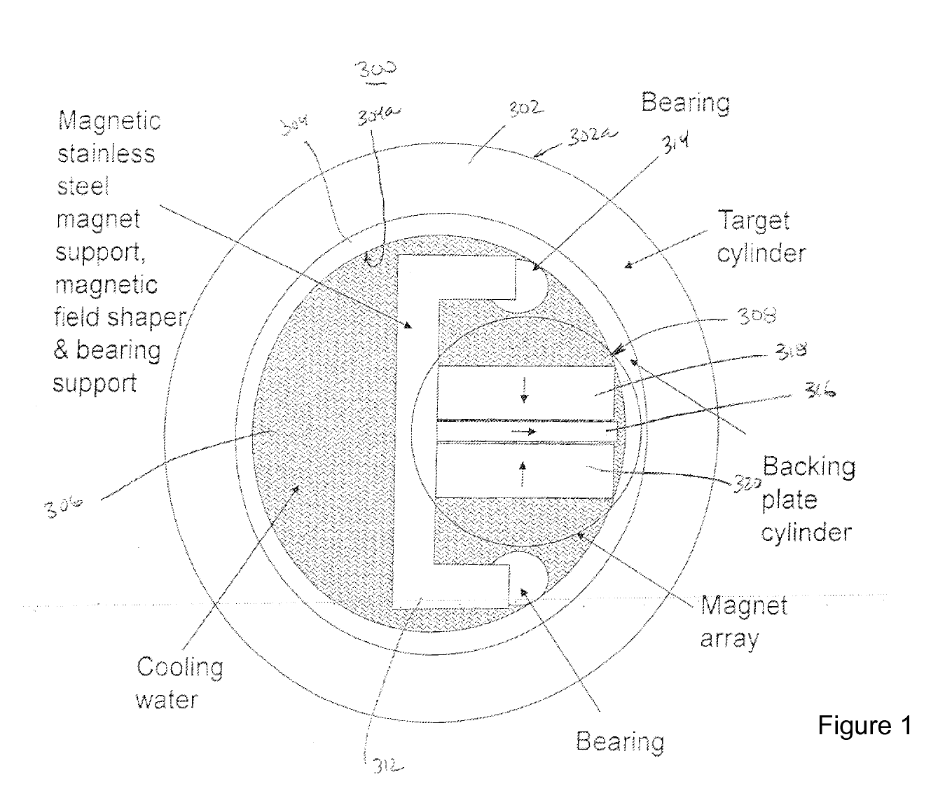

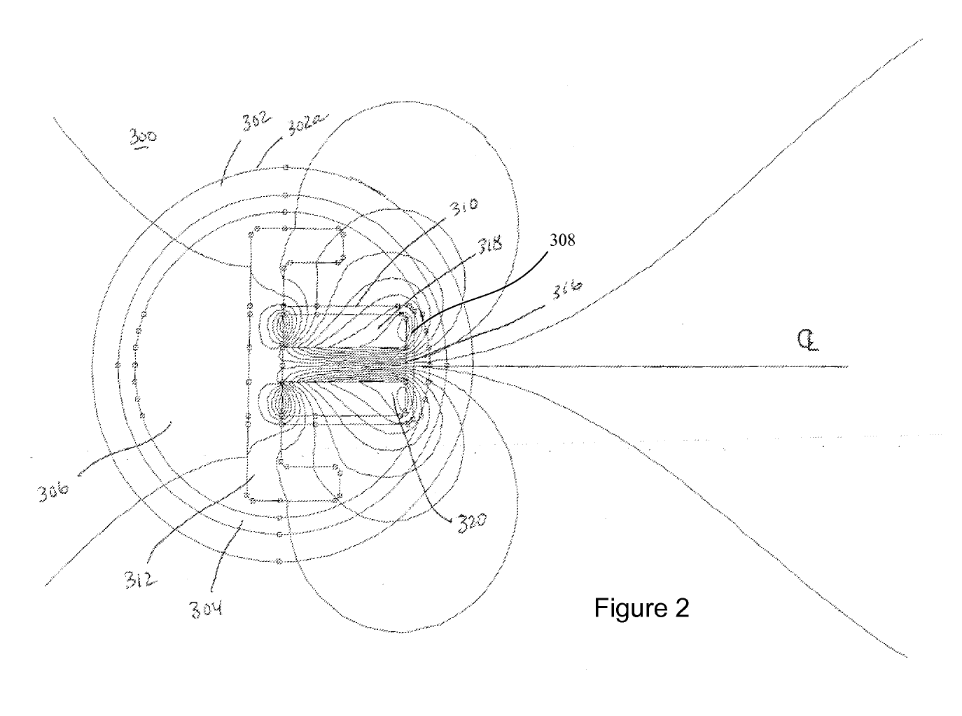

FIGS. 1 and 2 illustrate a cylindrical magnetron sputter source assembly 300 that includes a rotatable cylindrical sputtering target 302 formed on a stainless steel backing cylinder 304 which can be cooled by water 306 circulating the length of the backing cylinder 304. A magnet array 308 is housed in a stainless steel hermetically sealed magnet array housing 310 that protects the magnet array 308 from corrosion by the cooling water 306. The magnet array housing 310 is hermetically sealed to a stainless steel stainless steel magnet support and field shaper 312. The magnet support and field shaper 312 serve as a housing for support bearings 314 and also direct the residual magnetic field from the back and sides of the magnet array 308 to the target cylinder 302 to further enhance the flux appearing at the target surface 302a and to provide for a more compact configuration. As will be appreciated by those skilled in the art, the bearings 314 ride on the inside surface 304a of the backing cylinder 304 and prevent the magnet array 308 from contacting the backing cylinder 304. Not shown in FIGS. 1 and 2, for illustrative simplicity, is a structure for mounting and rotating the cylindrical magnetron sputtering cathode assembly 300 and for providing cooling water 306 to the interior of the backing cylinder 304.

As discussed above, the cylindrical magnetron sputter source assembly illustrated in FIGS. 1 and 2 enhances flux appearing at the target surface 302a and provides for a more compact configuration. One skilled in the art will readily appreciate that clean room space is costly and additional chambers required to accommodate a sufficient number of typical magnetron sources can be prohibitively expensive. For example, multilayer planar magnetron sources utilize and store relatively little target material and production must often be interrupted to change the targets. Multilayer planar magnetron sources, for example, have little space for magnets, resulting in relatively low magnetic field strength that limits the range of operating pressure of the cathodes. Hence, the thickness of non-ferrous target materials is limited and the thickness of ferromagnetic materials such as cobalt and cobalt alloys is even more limited.

A cylindrical magnetron sputter source assembly 300 according to various embodiments incorporates a compact magnet array 308 configured to accommodate the curvature of the target cylinder 302, magnet support and field shaper 312, and bearings 314. A magnet array 308 according to various embodiments provides for a reduced size, allowing for a net increase in the number of magnetron sources that can fit within a particular sputter tool chamber relative to planar magnetron sources, for example.

In some embodiments, the sputtering target cylinder 302 may comprise a 0.1 inch (2.54 mm) thick Co target, formed on a 316 stainless steel backing cylinder 304 that is internally cooled by water 306 circulating the length of the backing cylinder 304. A magnet assembly that includes a plurality of Halbach magnet arrays 308 is housed in a 316 stainless steel hermetically sealed housing 310 that protects the magnet arrays 308 from corrosion by the cooling water 306.

The Halbach magnet array 308 in the embodiment shown in FIGS. 1 and 2 includes a centrally positioned unidirectional magnet 316 with outwardly oriented polarity and a pair of upper and lower laterally positioned unidirectional magnets 318 and 320 with polarities oriented orthogonally to that of the central magnet 316, i.e. with downward and upward polarity, respectively, as indicated by the arrows in FIG. 1. The material of the Halbach magnet array may be, for example, NdFeB 50 MGOe.

According to various embodiments, in operation of the cylindrical magnetron sputter source assembly 300, the magnet array comprising magnet arrays 308 is maintained stationary while the cylindrical sputtering target 302 is rotated about its axis, thereby facilitating substantially full utilization (i.e., erosion by sputtering) of sputtering surface 302a. In this regard, cylindrical magnetron sputtering cathodes in accordance with embodiments of the disclosure are advantageous in comparison with planar magnetron sputtering cathodes, with which erosion (via sputtering) is generally limited to the target surface beneath the arch-shaped racetrack or tunnel regions.

As best shown in FIG. 2, the Halbach magnet array 308 produces a significantly stronger transverse magnetic field at the surface 302a of the target 302 than does a magnet array of a typical cylindrical magnetron sputter source implementation, thus allowing thicker targets to be utilized. The Halbach magnet array 308 also brings the sputter tracks that run the length of the cylinder closer to the centerline than any standard cathode (either planar or cylindrical). This serves to increase the collection efficiency of the sputtered material.

As stated above, the magnetic stainless steel magnet support and field shaper 312, which serves as a housing for the support bearings 314, also directs the residual magnetic field from the back and sides of the magnet array 308 to the target 302 to further enhance the flux appearing at the target surface 302a. This is particularly useful when target materials with high magnetic saturation are used, allowing thicker targets to be used.

A cylindrical magnetron sputter source assembly implemented in accordance with embodiments consistent with FIGS. 1 and 2 provides for an increase in the density of racetrack traces that are located close to the substrate, reduced material waste, and a reduction in the amount of sputtered material deposited at low angles on the substrate that can otherwise result in undesirable film porosity characteristics as compared to standard magnetron sources. Further, when utilizing a cylindrical sputter source according to various embodiments, there is created an intensely trapped racetrack drift zone to quickly “burn” through any layers of the target that have not reacted with the chamber residual gases, such as water, oxygen and nitrogen, during the “no-sputter” portion of the rotation cycle.

A cylindrical magnetron sputter source in accordance with various embodiments of the disclosure can provide for one or more of sputtering of thicker ferromagnetic and non-magnetic target materials, installing of a greater number of sputter sources per unit length of an in-line sputter system, a reduction in system downtime for target change because of greater target utilization and volume, increased film collection efficiency, and improved operation in a reactive gas environment as compared to standard planar or cylindrical magnetron sputter sources. A cylindrical magnetron sputter source in accordance with various embodiments of the disclosure is particularly well suited for use in the manufacture of various types of thin film-based recording media, such as for example, magnetic and magneto-optical media, as well as CD and DVD-based media.

It is to be understood that even though numerous characteristics and aspects of various embodiments have been set forth in the foregoing description, together with details of the structure and function of various embodiments, this detailed description is illustrative only, and changes may be made in detail, especially in matters of structure and arrangements of parts to the full extent indicated by the broad general meaning of the terms in which the appended claims are expressed.

What is claimed is:

1. A cylindrical magnetron sputter source comprising:
a rotatable cylindrical sputtering target;
a stationary magnet assembly that includes a plurality of Halbach magnet arrays disposed within the cylindrical sputtering target; and
a magnetic magnet support and field plate disposed within the cylindrical sputtering target and to which the magnet assembly is attached.

2. The cylindrical magnetron sputter source of claim 1, wherein each of the Halbach magnet arrays comprises a centrally positioned unidirectional magnet with radially outwardly oriented polarity, a first laterally positioned unidirectional magnet with polarity oriented orthogonally downward with respect to the central magnetic, and a second laterally positioned unidirectional magnet with polarity oriented orthogonally upward with respect to the central magnet.

3. The cylindrical magnetron sputter source of claim 1, and further comprising:
a magnet assembly housing in which the magnet assembly is disposed, the magnet assembly housing being hermetically attached to the magnetic magnet support and field plate.

4. A cylindrical magnetron sputter source comprising:
a rotatable cylindrical sputtering target formed on a backing cylinder;
a magnet assembly that is disposed within the backing cylinder to be stationary relative to the rotatable cylindrical sputtering target, the magnet assembly including a plurality of Halbach magnet arrays;
a magnetic magnet support and field shaper disposed within the backing cylinder; and
a magnet assembly housing in which the magnet assembly is disposed, the magnet assembly housing being hermetically attached to the magnet support and field shaper,
the magnet support and field shaper having a plurality of bearings formed as a part thereof such that the bearings ride on an inside surface of the backing cylinder and prevent the magnet assembly housing from contacting the backing cylinder.

5. The cylindrical magnetron sputter source of claim 4, wherein each of the Halbach magnet arrays comprises a centrally positioned unidirectional magnet with radially outwardly oriented polarity, an upper laterally positioned unidirectional magnet with polarity oriented orthogonally downward with respect to the central magnet, and a lower laterally positioned unidirectional magnet with polarity oriented orthogonally upward with respect to the central magnet.

6. The cylindrical magnetron sputter source of claim 5, wherein the central magnet, the upper laterally positioned unidirectional magnet and the lower laterally positioned unidirectional magnet comprise NdFeB 50 MGOe.

7. The cylindrical magnetron sputter source of claim 4, wherein the backing cylinder comprises stainless steel.

8. The cylindrical magnetron sputter source of claim 4, wherein the magnet array housing comprises stainless steel.

9. The cylindrical magnetron sputter source of claim 4, wherein the magnetic magnet support and field shaper comprises stainless steel.

10. In a cathode sputter system, a method comprising:
(a) in the cathode sputter system, using a cylindrical magnetron sputter source, electrically connected as a cathode electrode, having:
i. a rotatable cylindrical sputtering target;
ii. a stationary magnet assembly that includes a plurality of Halbach magnet arrays disposed within the cylindrical sputtering target; and
iii. a magnetic magnet support and field plate disposed within the cylindrical sputtering target and to which the magnet assembly is attached;
(b) evacuating the volume of the cathode sputter system in which a substrate is situated;
(c) introducing an inert gas into the evacuated volume;
(d) applying a high voltage electric field between the cylindrical magnetron sputter source connected as a cathode electrode and an anode electrode within the cathode sputter system to generate a plasma within the evacuated volume;
(e) rotating the cylindrical sputtering target while the plasma is present; and,
(f) depositing a thin film of the target material on the surface of the substrate held within the cathode sputter system.

11. The method of claim 10 wherein the stationary magnet assembly Halbach magnet arrays each include a centrally positioned unidirectional magnet with radially outwardly oriented polarity, a first laterally positioned unidirectional magnet with polarity oriented orthogonally downward with respect to the central magnetic, and a second laterally positioned unidirectional magnet with polarity oriented orthogonally upward with respect to the central magnet.

12. The method of claim 11 wherein the central magnet, the upper laterally positioned unidirectional magnet and the lower laterally positioned unidirectional magnet comprise NdFeB 50 MGOe.

13. In a cathode sputter system, a method comprising:
(a) in the cathode sputter system, using a cylindrical magnetron sputter source, electrically connected as a cathode electrode, having:
i. a rotatable cylindrical sputtering target formed on a backing cylinder;
ii. a magnet assembly that is disposed within the backing cylinder to be stationary relative to the rotatable cylindrical sputtering target, the magnet assembly including a plurality of Halbach magnet arrays;
iii. a magnetic magnet support and field shaper disposed within the backing cylinder; and
iv. a magnet assembly housing in which the magnet assembly is disposed, the magnet assembly housing being hermetically attached to the magnet support and field shaper, the magnet support and field shaper having a plurality of bearings formed as a part thereof such that the bearings ride on an inside surface of the backing cylinder and prevent the magnet assembly housing from contacting the backing cylinder;
(b) evacuating the volume of the cathode sputter system in which a substrate is situated;
(c) introducing an inert gas into the evacuated volume;
(d) applying a high voltage electric field between the cylindrical magnetron sputter source connected as a cathode electrode and an anode electrode within the cathode sputter system to generate a plasma within the evacuated volume;
(e) rotating the cylindrical sputtering target while the plasma is present; and,
(f) depositing a thin film of the target material on the surface of the substrate held within the cathode sputter system.

14. The method of claim 13 wherein the stationary magnet assembly Halbach magnet arrays each include a centrally positioned unidirectional magnet with radially outwardly oriented polarity, a first laterally positioned unidirectional magnet with polarity oriented orthogonally downward with respect to the central magnetic, and a second laterally positioned unidirectional magnet with polarity oriented orthogonally upward with respect to the central magnet.

15. The method of claim 14 wherein the central magnet, the upper laterally positioned unidirectional magnet and the lower laterally positioned unidirectional magnet comprise NdFeB 50 MGOe.

16. The method of claim 13 wherein the backing cylinder comprises stainless steel.

17. The method of claim 13 wherein the magnet array housing comprises stainless steel.

18. The method of claim 13 wherein the magnetic magnet support and field shaper comprise stainless steel.
